(19) United States
(12) Patent Application Publication
(10) Pub. No.: US 2015/0076675 A1
(43) Pub. Date: Mar. 19, 2015

(54) LEADFRAME PACKAGE WITH WETTABLE SIDES AND METHOD OF MANUFACTURING SAME

(71) Applicant: STMicroelectronics, Inc., Laguna (PH)

(72) Inventors: Rogelio Real, Calamba (PH); William Cabreros, Sta Rosa (PH)

(73) Assignee: STMicroelectronics, Inc., Laguna (PH)

(21) Appl. No.: 14/027,975

(22) Filed: Sep. 16, 2013

(51) Int. Cl. H01L 23/00

(52) U.S. Cl. CPC H01L 24/44; H01L 24/89
USPC 257/676; 438/112

(57) ABSTRACT

Embodiments of the present disclosure are directed to leadframe packages with wettable sides and methods of manufacturing same. In one embodiment, the leads of the leadframe packages have recesses with a curved profile formed therein. The recesses are plated with a solder wettable layer of conductive material that enables solder to flow along the surface during surface mounting of the package to a board, such as a PCB.

### BACKGROUND

1. Technical Field

Embodiments of the present disclosure are directed to leadframe strips and leadless packages, as well as methods of manufacturing leadframe strips and assembling leadless packages.

2. Description of the Related Art

Leadless (or no lead) packages are often utilized in applications in which small sized packages are desired. In general, flat leadless packages provide a near chip scale encapsulated package that includes a planar leadframe. Lands (also referred to as leads) located on a bottom surface of the package and, in many cases, side surfaces of the package provide electrical connection to a board, such as a printed circuit board (PCB). In that regard, the packages are mounted directly on the surface of the PCB using surface mount technology (SMT).

Although SMT allows for smaller packages, it also creates some disadvantages. In particular, the solder joints between the package and the PCB can be weakened due to the PCB and the package having different coefficients of thermal expansions (CTE). Thus, the reliability of the package may in some cases depend on the integrity of the solder joints.

As packages reduce in size, the available space for solder joints is further limited. Thus, strong solder bonds between the lands of the package and the pads of the board are desired.

### BRIEF SUMMARY

Embodiments of the present disclosure are directed to leadframe packages with wettable sides and methods of manufacturing same. In one embodiment, the leads of the leadframe packages have outer surfaces with recesses formed therein. The recesses have a curved profile and are plated with a wettable layer of conductive material that enables solder to flow along the outer surface during surface mounting of the package to a board, such as a PCB. This enables strong solder joints between the leads of the package and the board. The curved profile allows for the solder to flow into and fill the recess, thereby strengthening the bond.

Other embodiments are directed to a leadframe strip that is used for forming the leadframe packages described herein and methods of manufacturing same. In one embodiment, the leadframe strip reduces or eliminates molding flash that may migrate onto the outer surface of the leads of a leadframe package during a molding step of manufacturing leadframe packages.

### BRIEF DESCRIPTION OF THE SEVERAL VIEWS OF THE DRAWINGS

FIG. 1A is a cross-sectional view of a leadframe package made in accordance with one embodiment of the present disclosure.

FIG. 1B is a side view of the leadframe package of FIG. 1A.

FIGS. 2A-2M illustrate side views of a portion of a conductive foil that is formed into a leadframe strip at various stages of manufacturing in accordance with one embodiment of the present disclosure.

FIG. 2N illustrates a top view of the leadframe strip of FIG. 2M.

FIG. 2O illustrates a bottom view of the leadframe strip of FIG. 2M.

FIGS. 3A-3F illustrate cross-sectional views of various stages of assembly of leadframe packages, such as the leadframe package of FIG. 1, in accordance with an embodiment of the present disclosure.

### DETAILED DESCRIPTION

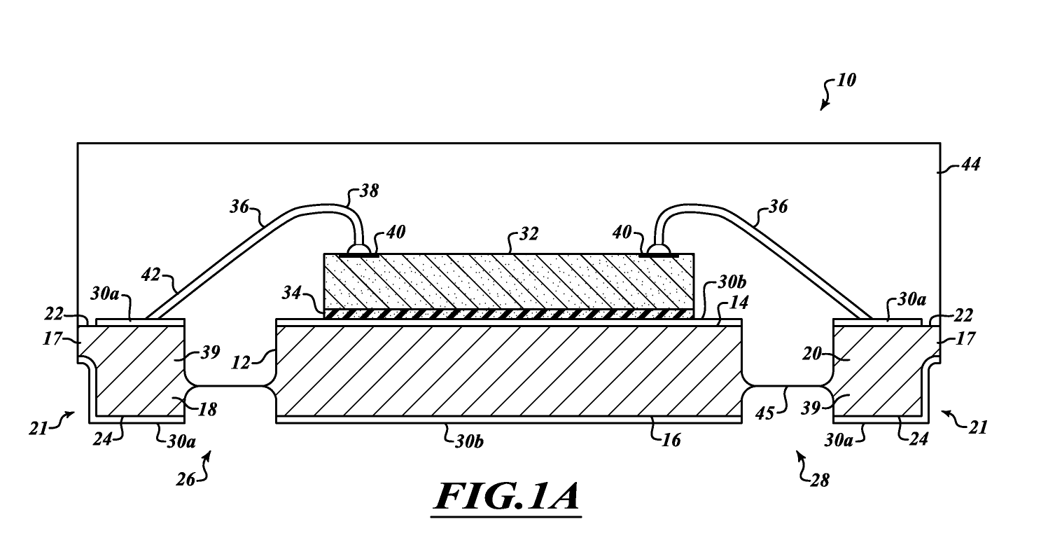

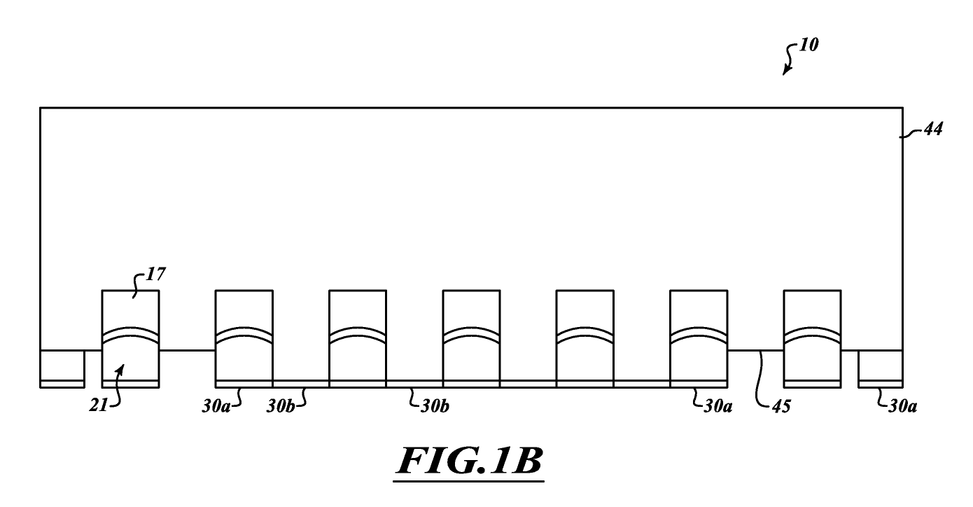

FIG. 1A shows a cross-sectional view of a leadframe package 10 made in accordance with one embodiment of the disclosure. FIG. 1B is a side view of the leadframe package 10. The package 10 includes a die pad 12 having upper and lower surfaces 14, 16. The package 10 further includes first and second leads 18, 20, each having upper and lower surfaces 22, 24. The first lead 18 is located proximate a first side of the die pad 12, and the second lead 20 located proximate a second side of the die pad 12. The lower surfaces 24 of the leads 18, 20 are also referred to as lands of the package 10.

It is to be appreciated that any number of leads may be located proximate any number of sides of the die pad, including only one lead located proximate one side of the die pad.

An outer surface 17 of the first and second leads 18, 20 have a recess 21 formed therein. The recess 21 in the illustrated embodiment extends more than halfway through the thickness of the leads 18, 20. In other embodiments, however, the recess may extend approximately halfway through the thickness of the leads or less than halfway through the thickness of the leads. At least a portion of the recess 21 has a curved radius. The recess extends across the entire width of each lead 18, 20 as best shown in FIG. 1B.

As will be explained in more detail below, the curved radius of the recess 21 of the leads 18, 20 allows for a strong solder joint between the package 10 and a board (not shown), such as printed circuit board. The recess 21 forms a wettable surface that enables solder to flow along the surface during surface mounting of the package 10. In particular, during surface mounting of the package, solder flows up into the curvature of the recess and fills the curvature, creating a strong bond during surface mount. In that regard, the radius of curvature of the recess 21 may be any radius that allows solder to flow in and fill the curvature.

Upper and lower surfaces 14, 16 of the die pad 12 may be plated with a conductive layer 30b. Additionally, at least portions of the upper and lower surfaces 22, 24 of the first and second leads 18, 20 and the recesses 21 therein are plated with the conductive layer 30a. In the illustrated embodiment, the lower surface 24 of the first and second leads 18, 20 and the recesses 21 are plated with the conductive layer 30a. A portion of the upper surfaces 22 of the first and second leads 18, 20 are plated with the conductive layer 30a, while an outer portion of the upper surfaces 22 remains unplated.

The conductive layers 30a and 30b may be a nanolayer or microlayer of one or more conductive materials. For instance, the upper and lower surfaces 14, 16 of the die pad 12 and the upper and lower surfaces 22, 24 of the leads 18, 20 may be plated with one or more metal materials, such as Ni/Pd/Ag, Ni/Pd/Au—Ag alloy, or Ni/Pd/Au/Ag. As will be explained below, the conductive layer 30 may be used in some embodiments as a mask layer for etching portions of the leadframe material during assembly.

A semiconductor die 32 that includes an electrical device, such as an integrated circuit, is secured to the conductive layer 30b over the upper surface 14 of the die pad 12 by an adhesive material 34. The adhesive material 34 may be any material configured to secure the die 32 to the die pad 12, such as glue, paste, tape, and the like.

Conductive wires 36 electrically couple the die 32 to the first and second leads 18, 20. For instance, a first end 38 of the conductive wire 36 is coupled to a bond pad 40 of the die 32 and a second end 42 of the conductive wire 36 is coupled to the first lead 18.

Encapsulation material 44 is located over the die pad 12 and the first and second leads 18, 20 enclosing the die 32 and the conductive wires 36. The encapsulation material 44 is also located between the first and second leads 18, 20 and the die pad 12 and forms a bottom surface 45 therebetween. The outer surface 17 of the first and second leads 18, 20 and the recesses 21 form outer side surfaces of the package 10 along with the encapsulation material 44.

As illustrated in FIG. 1A, the die pad 12 has curved edges proximate the bottom surface 45 of the encapsulation material 44. Similarly, inner surfaces 39 of the leads 18, 20 have curved surfaces proximate the bottom surface 45 of the encapsulation material 44.

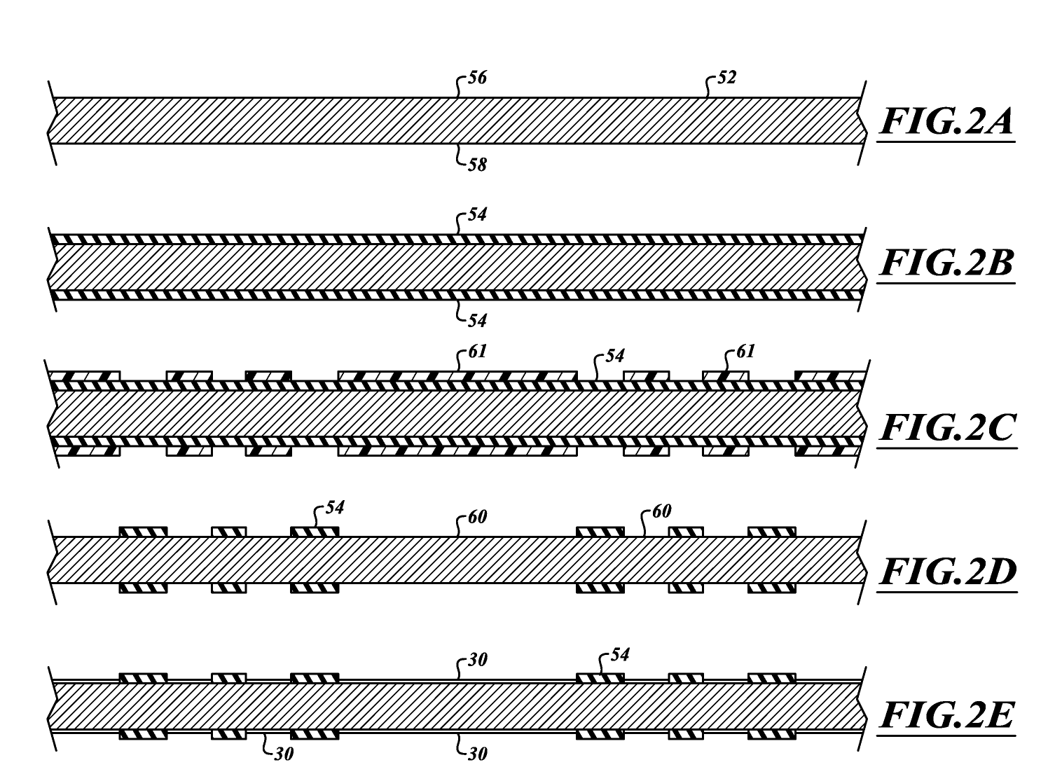

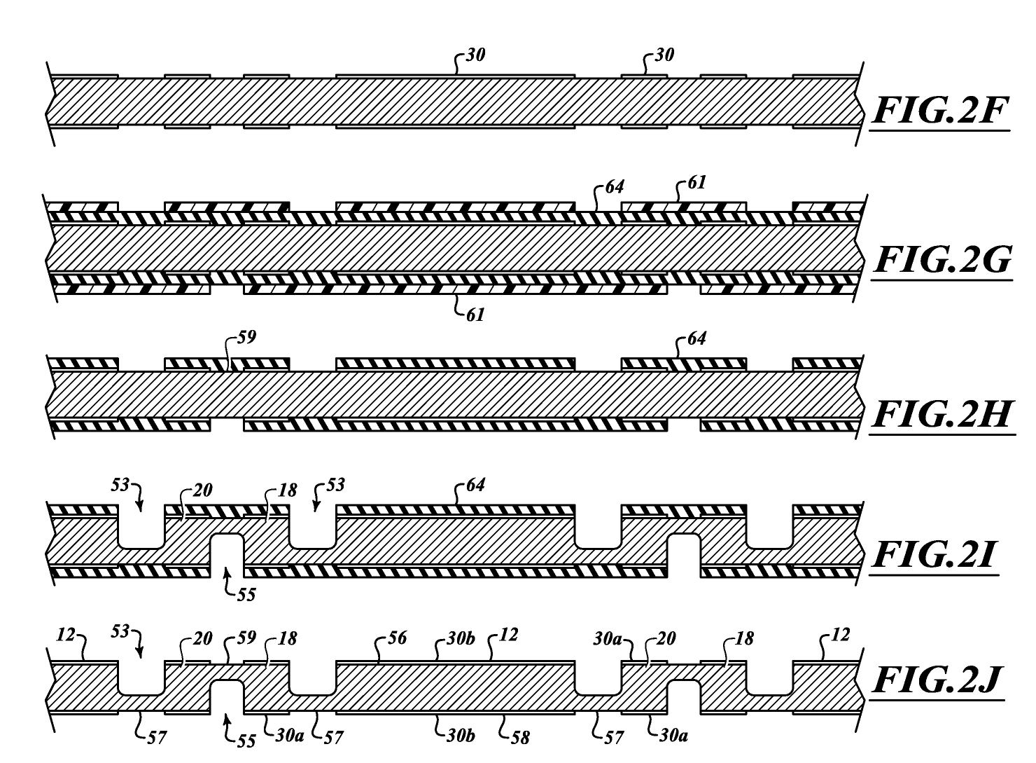

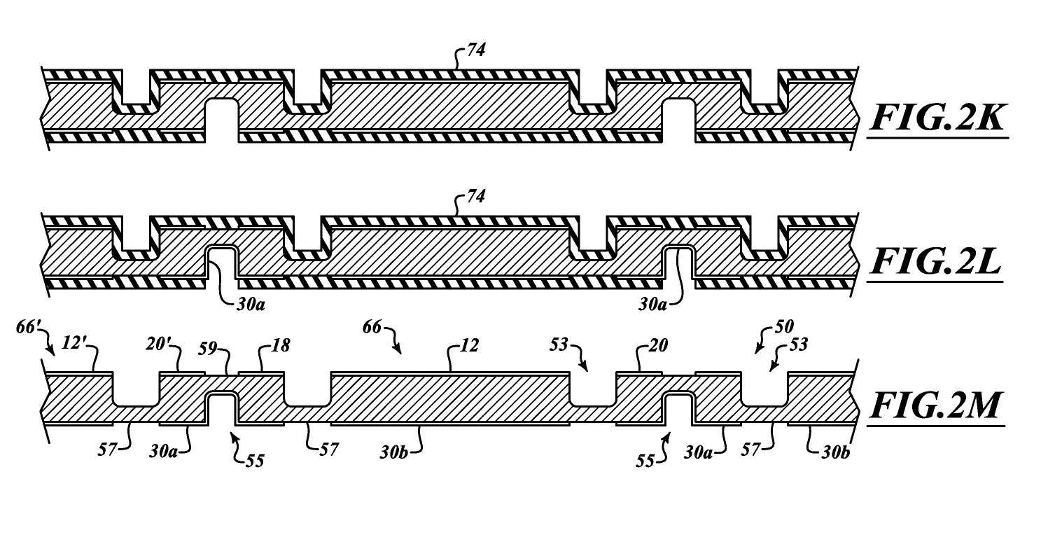

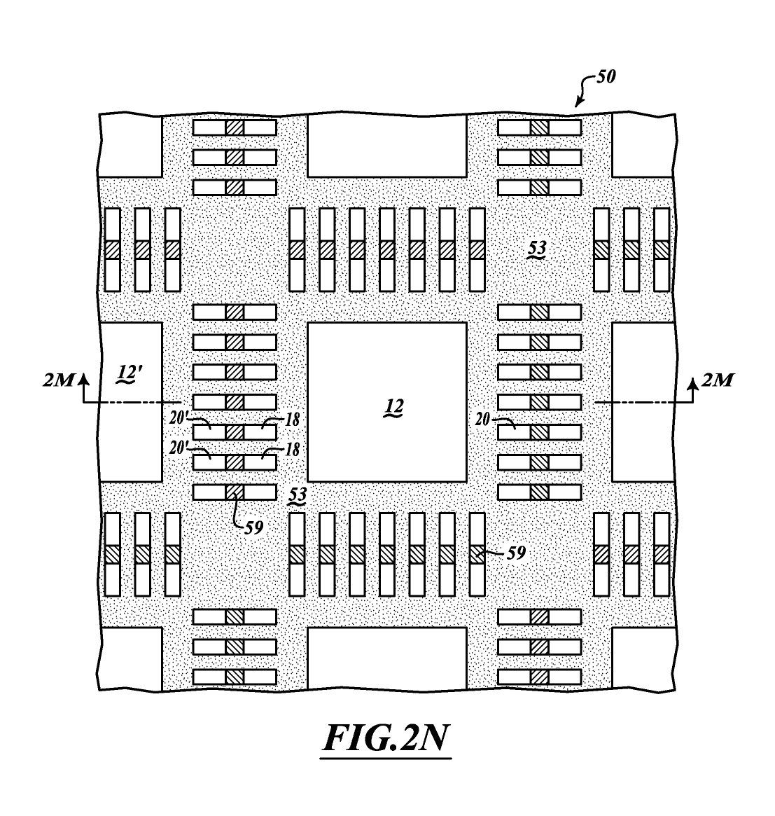

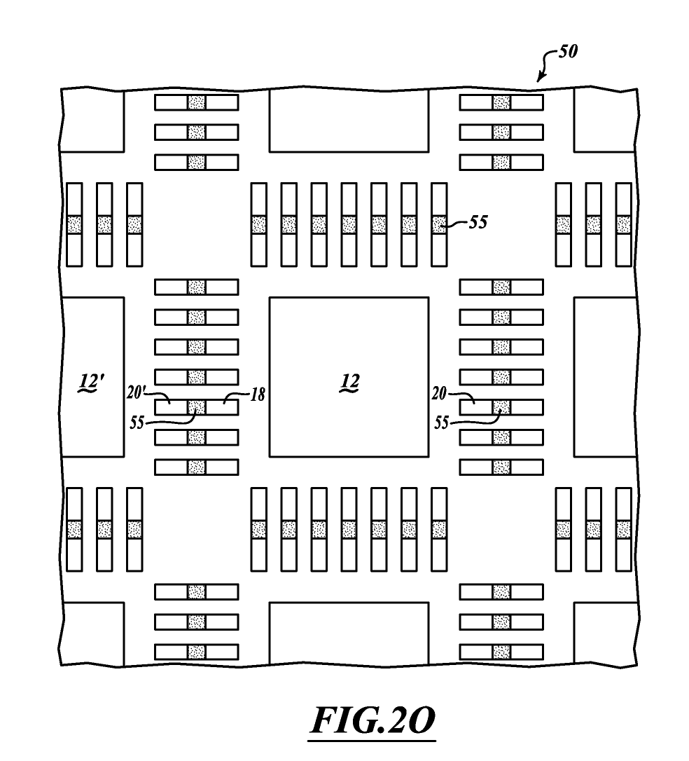

FIGS. 2A-2M illustrate side views of a portion of a conductive foil 52 that is formed into a leadframe strip 50 (FIG. 2M) at various stages of manufacturing in accordance with an embodiment of the present disclosure.

FIG. 2A shows a conductive foil 52 having first and second surfaces 56, 58 that is the base material for forming the leadframe strip 50. The conductive foil 52 may be a metal material and in some embodiments is made of copper or a copper alloy.

As shown in FIG. 2B, a light sensitive material 54, such as photoresist, is deposited on the first and second surfaces 56, 58 of the conductive strip 50. As shown in FIGS. 2C and 2D, portions of the light sensitive material 54 are patterned to form a mask layer. That is, portions of the light sensitive material 54 may be exposed to ultraviolet radiation 61 and then removed by a photoresist developer. In particular and as shown in FIG. 2D, exposed portions of the light sensitive material 54 are removed, leaving exposed portions 60 of the conductive foil 52 on the first and second surfaces 56, 58. Although the figures illustrate a positive photoresist, the photoresist may be a negative photoresist. That is, the photoresist that is exposed to ultraviolet radiation 61 becomes insoluble to the photoresist developer and remains on the surface.

As shown in FIG. 2E, a conductive layer 30 is formed, such as by plating techniques, on the exposed portions 60 of the conductive foil 52. The conductive layer 30 may include one or more conductive materials that are different materials from the conductive foil 52. The conductive material may be any material that encourages solder to flow along the surface during surface mount. As indicated above, the conductive layer 32 may be one or more materials, such as Ni/Pd/Ag, Ni/Pd/Au—Ag alloy, or Ni/Pd/Au/Ag.

As shown in FIG. 2F, the light sensitive material 54 is then removed from the first and second surfaces 56, 58, such as by conventional etching techniques, exposing the upper and lower surfaces of the conductive foil. The conductive layer 30 remains on the first and second surfaces 56, 58. As will be further explained below, the location at which the conductive layer 30 is formed on the conductive foil 52 corresponds to locations of the die pads 12 and first and second leads 18, 20 of the packages to be formed in the conductive foil 52. As shown in FIGS. 2G and 2H, another light sensitive material 64 is deposited and patterned on the conductive layer 30 on the first and second surfaces 56, 58 of the conductive foil 52. The light sensitive material 64 may be the same type of material as light sensitive material 54, such as photoresist, and may be positive or negative photoresist. In the illustrated embodiment, the light sensitive material 64 is patterned using known techniques, such as by radiation 61 and developer, as indicated in FIG. 2G, to produce patterned layers as shown in FIG. 2H.

FIG. 2H shows that the light sensitive material 64 remains located over the conductive layer 30 on both the first and second surfaces 56, 58 of the conductive foil 52. Additionally, the light sensitive material 64 is further located over an upper connecting bar 59 of the first surface 56 of the conductive foil 52. The light sensitive material 64 forms a mask layer for a subsequent etching step, such as an isotropic or anisotropic etch, that forms portions of the die pads 12 and leads 18, 20 as shown in FIG. 2I.

FIG. 2I shows the conductive foil 52 after an isotropic etch process. In one embodiment, the conductive foil 52 is etched by immersion in a bath of etchant and in some cases includes agitation techniques. In the bath, the conductive foil 52 is etched from the first surface 56 and from the second surface 58 of the conductive foil 52.

The etching of the conductive foil 52 forms a plurality of first recesses 53 in the first surface 56 and a plurality of second recesses 55 in the second surface 58. The first and second recesses 53, 55 have a curved profile that is formed during the etching step. After the etching step as shown in FIG. 2J, the light sensitive material 64 is removed from the upper and lower surfaces 14, 16 of the conductive foil 52.

Each of the first recesses 53 in the first surface 56 delimits a portion of a die pad 12 on one side and a portion of a lead 18 or 20 on the other side. The first recesses 53 form lower connection bars 57 that connect the leads 18, 20 to adjacent die pads 12. The first recesses 53 are optional. That is, in some embodiments, the first recesses 53 are not formed in the first surface 56. Although not shown in the cross-sectional view, leads that are located proximate the leads shown are connected together by lower connection bars as will be shown and described below in reference to FIG. 2O.

The second recesses 55 in the second surface 58 are formed to partially separate the first lead 18 from the second lead 20 and form an upper connecting bar 59 that connects the adjacent leads 18, 20 to each other. As best shown in FIG. 2J, the conductive layer 30 is presented by conductive layer 30b and 30a. It is to be appreciated that conductive layer 30b is on surfaces of die pads 12 and conductive layer 30a is on surfaces of leads 18 and 20.

In an alternative embodiment, one or both of the upper and lower surfaces 56, 58 of the conductive foil 52 are plated with the conductive layer 30 at locations which contain the first recesses 53 and the second recesses 55 along with the other portions of the upper and lower surfaces 56, 58 as illustrated in FIG. 2F. Then, during the etch step of FIG. 2I, the etch chemistry etches through the conductive layer 30 and the conductive foil 52. This embodiment reduces the possibility of misalignment of the light sensitive material 64 that is patterned on the conductive layer 30. In that regard, the location of the first and second recesses 53 and 55 are established in one step rather than two separate steps.

As indicated in FIG. 2K, another light sensitive material 74 is deposited and patterned on the conductive layers 30a and 30b on the first and second surfaces 56, 58 of the conductive foil 52 using the techniques mentioned above. The light sensitive material 74 may be the same type of material as light sensitive materials 54 and 64, such as photoresist, and may be positive or negative photoresist. The light sensitive material 74 is deposited in the first recesses in the first surface 56. The light sensitive material 74, however, is not deposited in the second recesses 55 in the second surface 58. As shown in FIG. 2L, the second recesses 55 in the second surface 58 are plated with conductive layer 30.

As shown in FIG. 2M, the light sensitive material 74 is removed from the first and second surfaces 56, 58 thereby forming a leadframe strip 50 for assembling a plurality of packages. The leadframe strip 50 includes a plurality of package frames 66 that each includes a die pad 12 connected to at least one first lead 18 and at least one second lead 20 by lower connecting bars 57. Leads that are associated with adjacent package frames 66 of the plurality of package frames are connected by the upper connecting bar 59. For instance and as shown in FIG. 2M, a first lead 18 is associated with a first die pad 12 of a first package frame 66. A second lead 20′ is associated with a second die pad 12′ of a second package frame 66′. The first lead 18 of the first package frame 66 is coupled to the second lead 20′ of the second package frame 66′ by the upper connecting bar 59.

As shown in FIG. 2M, portions of the leadframe strip 50 remain unplated. In particular, the portions of the leadframe strip 50 that remain unplated include upper and lower surfaces of the lower connecting bars 57 and the upper surface of the upper connecting bar 59. As will be explained below, the plated layer 30 forms a mask layer of the leadframe strip 50 during assembly.

FIG. 2N shows a top view of the conductive strip 50. The gray shading portion indicates the recesses 53 formed in the upper surface 56 of the conductive strip to form the lower connecting bars 57. That is, the gray shading portion illustrates the portions that are recessed relative to the first surface 56 of the die pads 12 and the leads 18, 20 of the conductive strip 50. Adjacent leads 18 and 18 that are proximate the same die pad 12 are connected to one another by lower connecting bars 57. The cross hatching of the upper connecting bar 59 indicates that the upper connecting bar 59 is in a different plane than the conductive plated die pads 12 and leads 18, 20 because upper connecting bar 59 is not plated with the conductive layer 30a.

Although seven leads are associated with each side of the die pad 12 for each package frame in the illustrated embodiment, it is to be appreciated that any number of leads may be associated with any number of sides of the die pad. For instance, in one embodiment only one lead may associated with a single side of the die pad. In another embodiment, two leads may be associated with one or more sides of the die pad.

FIG. 2O shows a bottom view of the conductive strip 50. The gray shading portion indicates the recesses 55 formed in the second surface 58 of the conductive strip 50 to form the upper connecting bars 59. In particular, the gray shading portion illustrates the portions that are recessed relative to the other portions of second surface of the conductive strip 50.

The leadframe strip 50 as shown in FIGS. 2M, 2N, and 2O may be used to assemble leadframe packages, such as the leadframe package 10 of FIG. 1, as will be explained below.

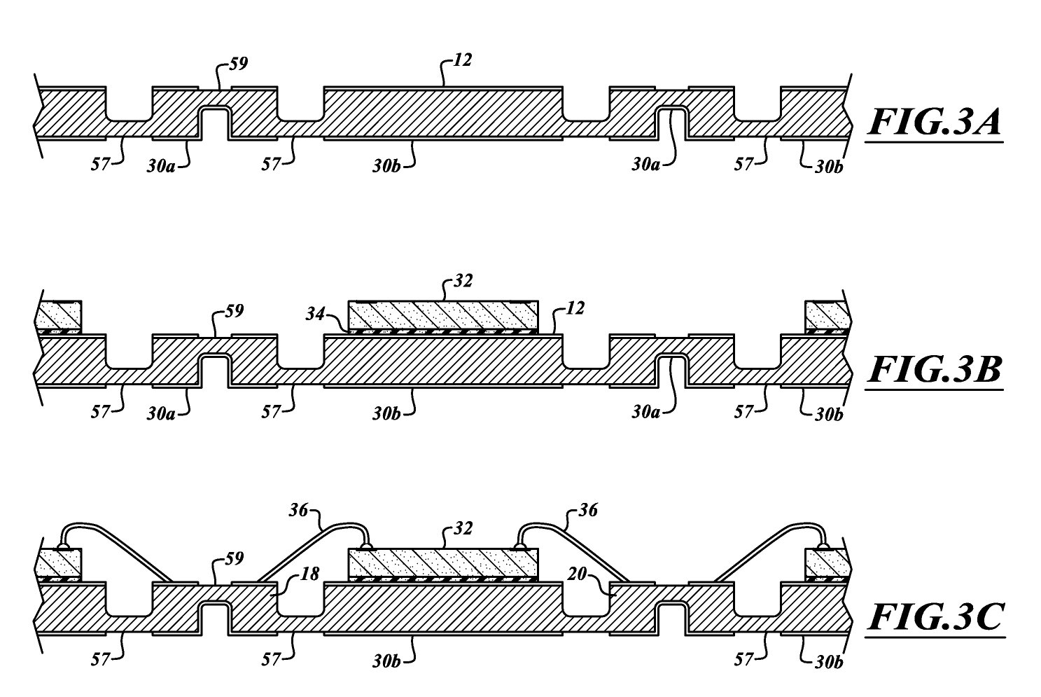

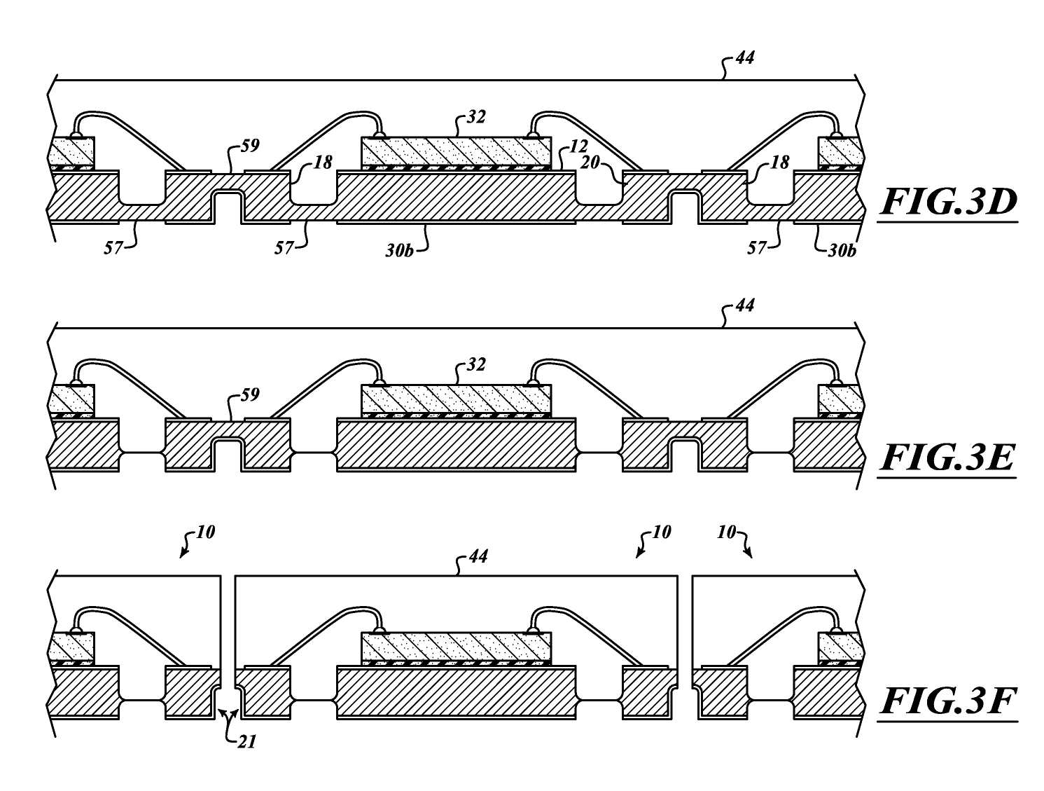

FIGS. 3A-3F illustrate cross-sectional views of various stages of assembly of leadframe packages, such as the package 10 of FIGS. 1A and 1B, in accordance with an embodiment of the present disclosure. As shown in FIG. 3A, the assembly process begins with a leadframe strip, such as the leadframe strip 50 of FIGS. 2M, 2N, 2O.

In general, the leadframe strip 50 may be suitably rigid such that a supporting structure such as tape may not be used. This is due in part to the lower connecting bars 57 and the upper connecting bars 59 adding rigidity to the strip. It is to be appreciated, however, that in some embodiments the assembly process may include using a supporting structure during at least a portion of the assembly process.

FIG. 3B shows that semiconductor dice 32 are placed over the upper surface 14 of the die pads 12 of the leadframe strip 50. The semiconductor dice 12 may be secured to the die pads 12 by adhesive material 34, such as tape, paste, glue, or any material that suitably adheres the die to the die pad. The semiconductor die 32 may include an electrical device, such as an integrated circuit.

As shown in FIG. 3C, each die 32 are electrically coupled to a first lead 18 and a second lead 20. In the illustrated embodiment, a first end of a first conductive wire 36 is coupled to a bond pad of the die 32 and a second end of the conductive wire 36 is coupled to the first lead 18. A first end of a second conductive wire 36 is coupled to a bond pad of the die 32 and a second end of the conductive wire 36 is coupled to the second lead 20.

Although not shown, the dice 32 may be electrically coupled to the lead sets, such as by flip chip arrangement, as is well known in the art. That is, each die would be larger than shown in FIGS. 3B-3F so that the outer perimeter of each die would be located on the upper surface of adjacent leads. In a flip chip arrangement, solder balls located between the die and the lead would provide electrical communication therebetween. In this arrangement, the leads may provide electrical and mechanical support for the die. In these embodiments, the leadframe strip may not include die pads and thus, the lower connecting bars 57 would couple adjacent leads within a package frame rather than couple leads to the die pad.

As shown in FIG. 3D, encapsulation material 44 is formed over the upper surfaces of the leadframe strip 50 so that the encapsulation material 44 surrounds the die 32, the conductive wires 36, and upper surface of the leadframe strip 50. The encapsulation material 44 is also provided in the recesses 53 in the upper surface and thus extends along a portion of the side surfaces of the die pad 12 and the leads 18, 20. The encapsulation material 44 is an insulative material that protects the electrical components and materials from damage, such as corrosion, physical damage, moisture damage, or other causes of damage to electrical devices and materials. In one embodiment, the encapsulation material 44 is a polymer.

The encapsulation material 44 may be formed on the leadframe strip 50 by conventional techniques, for example by a molding process, and in some embodiments is hardened during a curing step. The lower connecting bars 57 and the upper connecting bars 59 are able to prevent or at least reduce mold flash. That is, due to the lower connecting bars 57 and the upper connecting bars 59, the encapsulation material 44 does not readily flow between the second surface 58 of the leadframe strip 50 and an inner surface of the mold (not shown).

It is to be appreciated that in the prior art, there are openings between the die pad and the leads that can cause molding flash. In that regard, during the molding process, encapsulation material can in some cases flow through the opening and between the inner surface of the mold and the second surface of the leadframe strip, including onto the bottom surface of the leads or lands. The encapsulation material is an insulative material and thus reduces the amount of surface area of the lead that can be used for making electrical connection with a board during surface mount. Thus, by reducing molding flash by one or more embodiments of the present invention, the solder joint bond at surface mount is strengthened.

As shown in FIG. 3E, the lower connecting bars 57 are etched away using conventional etching techniques, such as those described above. In some embodiments, the conductive layer 30 forms a mask layer for removing the lower connecting bars 57. In another embodiment, a light sensitive material (not shown) may be deposited over the conductive layer 30 or a bottom surface of leadframe to form a mask layer. In such an embodiment, the conductive layer 30 or the bottom surface of the leadframe would not need to be resistant to the etch chemistries.

A lower surface of the encapsulation material 44 forms an etch stop for etching the lower connecting bars 57. After the etch step, the die pads 12 are separated from the leads 18, 20 and adjacent leads within the same package frame are separated from each other. The removal of the lower connecting bars 57 electrically isolates the die pads from the leads and adjacent leads from each other, while at the same time maintaining mechanical connection to each other by the encapsulation material 44. As shown in FIG. 3E, the upper connecting bars 59 are not separated during the etch step.

The manufacturing process further includes separating each package into individual packages 10 as shown in FIG. 3F. In particular, the packages 10 are separated through a portion of the upper connecting bars 59 and the encapsulation material 44 located above the portion of the upper connecting bars 59.

The packages 10 can be separated by various dicing methods, including saw and laser. The saw blade or laser used for separating the packages 10 has a cutting width that is less than a width of the upper connecting bars 59 such that a recess is formed in the outer edge 17 of the leads 18, 20 (FIG. 1A). As discussed above, the recesses in the leads have a curved profile and provide wettable surfaces for solder to flow across and fill for increased solder joint strength.

By forming lower and upper connecting bars between die pads and leads and between adjacent leads, various benefits are obtained. In particular, the solder joint between the package and a board may be strengthened. As discussed above in or more embodiments, by having upper and lower connecting bars during the encapsulation step, mold flash is reduced or prevented. That is, because the conductive strip does not include openings proximate the leads, the encapsulation material is prevented from flowing between the bottom surface of the leads and the inner surface of the mold. By preventing mold flash, the electrical connection during surface mount is significantly improved.

In addition, the upper connecting bars result in the formation of recesses with curved profiles in the outer surface of the leads. These curved profile leads provide improved mechanical support of solder joints during surface mount. Furthermore, the curved profiles readily allow solder to flow therein and fill the curved profile, resulting in a stronger bond during surface mount. In contrast, if the recess was formed to have a right angle corner rather than a curved profile, solder would often fail to fill the corner, resulting in a weaker bond during surface mount.

In addition, the leadframe strip is suitably stiff for assembly process due to the upper and lower connecting bars such that a temporary supporting element is not needed.

The recess 21 also allows for a visual inspection during surface mount. That is, due to the solder flowing up the outer surface of the lead in the recess 21, the solder bond is visible along the side surface of the package. In that regard, an X-ray may not be needed to confirm proper solder attachment during surface mount, thereby increasing throughput during surface mount.

Moreover, by making the recess in the conductive strip prior to assembling the packages, the singulation step is more efficient and less costly. That is, cutting through encapsulation material is substantially easier than cutting through conductive material, such as copper. Thus, by sawing through the encapsulation material 44 and cutting a relatively small portion of the conductive strip, the sawing speed may be increased, thereby increasing throughput through the sawing tools. In addition, the blade life of the saw blades used to cut the packages into individual packages will increase.

Typically, when sawing through connected leads of a leadframe strip, saw burrs can form on the outer edge of the lead. Thus, by having the leads attached at the bottom surface, saw burrs can affect the solder joints during surface mount. By cutting through the upper connecting bar, which is raised relative to the bottom surface of the lead, saw burs are substantially eliminated or significantly reduced.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method comprising:
coupling a first semiconductor die to an upper surface of a first die pad of a first package frame of a leadframe strip, the first package frame including a plurality of leads connected to the first die pad by first lower connection bars;
coupling a second semiconductor die to an upper surface of a second die pad of a second package frame of the leadframe strip, the second package frame including a plurality of leads coupled to the second die pad by second lower connection bars, the first package frame being adjacent the second package frame, the plurality of leads of the first package frame being coupled to the plurality of leads of the second package frame by upper connection bars;
coupling a first end of a first wire bond to a pad of the first semiconductor die and a second end of the first wire bond to a first lead of the first package frame;
coupling a first end of a second wire bond to a pad of the second semiconductor die and a second end of the second wire bond to a second lead of the second package frame;
encapsulating the first semiconductor die, the second semiconductor die, and the first and second wire bonds with encapsulation material;
electrically isolating the leads from the semiconductor die pad and adjacent leads of the same package frame by etching the lower connection bars; and
electrically isolating adjacent leads of adjacent package frames by cutting through the encapsulation material and the upper connection bars, each of the leads having a curved radius at an outer end of the lead that extends across a width of the lead.

2. The method of claim 1, wherein cutting comprises cutting with a saw blade or a laser.

3. The method of claim 1, wherein cutting comprises cutting with a saw blade that has a diameter that is smaller than a dimension of the upper connection bars.

4. The method of claim 1, wherein etching the lower connection bars comprises etching the lower connection bars so that a lower surface of the encapsulation material is exposed.

5. The method of claim 1, wherein encapsulating the first and second semiconductor dice and the first and second wire bonds with encapsulation material comprises placing the leadframe strip in a mold and flowing encapsulation material across an upper surface of the leadframe strip.

6. The method of claim 1, wherein etching the lower connection bars comprises forming curved surfaces along at least a portion of the die pads and an inner surface of the leads proximate a bottom surface of the encapsulation material.

7. A semiconductor package comprising:
a die pad having upper and lower surfaces;
a semiconductor die having a bond pad coupled to the upper surface of the die pad;
a plurality of leads located proximate at least one side of the die pad, an outer surface of each of the plurality of leads including a recess with a curved profile, the recess extending along an entire width of the lead;
a wire bond having a first end coupled to one of the leads and a second end coupled to the bond pad of the semiconductor die; and
encapsulation material located over the semiconductor die, the wire bond, and a portion of the plurality of leads.

8. The semiconductor package of claim 7, wherein an inner surface of each of the leads includes a curved edge proximate a lower surface of the encapsulation material.

9. The semiconductor package of claim 7, wherein the die pad includes a curved edge proximate a lower surface of the encapsulation material.

10. The semiconductor package of claim 7, wherein the plurality of leads include a conductive layer on a lower surface of the leads and in the recess.

11. The semiconductor package of claim 10, wherein the conductive layer includes one or more metal materials.

12. The semiconductor package of claim 7, further comprising wire bonds having a first end coupled to a respective pad of the semiconductor die and a second end coupled to a respective one of the leads.

13. The semiconductor package of claim 7, wherein a radius of curvature of the curved profile of the recess in the outer surface of each of the plurality of leads is substantially greater than a radius of curvature of the curved edge of the die pad.

14. The semiconductor package of claim 7, wherein a surface of each lead that is proximate the die pad has a curved edge.

15. The semiconductor package of claim 7, wherein the recess extends more than halfway through a thickness of the leads.

16. A method of forming a leadframe strip comprising:
forming first recesses in an upper surface of a conductive foil by etching the upper surface of the conductive foil, the first recesses in the upper surface delimiting upper surfaces of die pads on a first side and inner surfaces of leads on a second side;
forming second recesses in a lower surface of the conductive foil by etching the lower surface of the conductive foil, the second recesses in the lower surface delimiting a portion of an outer surface of the leads and forming a lower connection; and
plating a conductive layer in the second recesses.

17. The method of claim 16, wherein etching the upper surface comprises etching more than halfway through an entire thickness of the conductive foil.

18. The method of claim 16, wherein etching the lower surface comprises etching more than halfway through an entire thickness of the conductive foil.

19. The method of claim 16, further comprising depositing a conductive layer on portions of the upper and lower surfaces of the conductive foil.

20. The method of claim 19, wherein the first recesses are formed in portions of the upper surface of the conductive foil that remain exposed from the conductive layer.

21. The method of claim 16, further comprising forming third recesses in the upper surface of the conductive foil by etching the upper surface of the conductive foil, the third recesses in the upper surface delimiting leads that are adjacent to each other and proximate the same die.

22. The method of claim 21, wherein forming the first recesses and forming the third recesses are formed during a same etch step.

23. The method of claim 16, wherein forming the first recesses comprises etching through a conductive layer on the upper surface of the conductive foil and etching partway through the upper surface of the conductive foil.
